(19) United States
(12) Patent Application Publication
(10) Pub. No.: US 2007/0076379 A1
(43) Pub. Date: Apr. 5, 2007

(54) PORTABLE ELECTRONIC APPARATUS EMPLOYING NUMERIC KEYPAD

(75) Inventors: Lin-Yun Hong, Shenzhen (CN); Zhi-Gang Liu, Shenzhen (CN); Hsuan-Chen Chen, Tu-Cheng (TW); Chien-Li Tsai, Tu-Cheng (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Taipei Hsien (TW)

(21) Appl. No.: 11/309,703

(22) Filed: Sep. 15, 2006

(30) Foreign Application Priority Data
Sep. 30, 2005 (CN) 200520065323.5

(51) Int. Cl. H05K 7/00

(52) U.S. Cl. 361/728; 361/733

(57) ABSTRACT

A portable electronic apparatus includes a case defining a space therein and an opening communicating with the space, and an input module received in the space of the case and configured for inputting data to the electronic apparatus. The input module includes a chassis detachably attached to the case, and a numeric keypad movably attached to the chassis through the opening. The numeric keypad is capable of being exposed from the case when data entry is desired. The space is suitable to receive a data storage device of the electronic apparatus when the input module is removed from the case.

### FIELD OF THE INVENTION

The present invention relates to portable electronic apparatuses, and particularly to a portable electronic apparatus employing a numeric keypad.

### DESCRIPTION OF RELATED ART

Portable electronic apparatuses such as notebook computers and laptop computers are constructed as compact as possible for portable purposes. In order to reduce the computers to compact sizes, parts of input modules generally associated with desktop computers are removed. For example, numeric keypads usually found on full size keyboards are eliminated from compact keyboards employed in the notebook computers in order to save space. When users input numbers with the compact keyboards, alphanumeric keys of the compact keyboards are used. Number entries can thus be inconvenient and time consuming for the users.

A kind of stand-alone numeric keypad is regarded as a solution to eliminate shortcomings of the above mentioned compact keyboards. The stand-alone numeric keypad is electrically connected to an electronic apparatus via an electronic cable. However, a combination of the stand-alone numeric keypad and the electronic apparatus may greatly increase a volume of the electronic apparatus. Furthermore, the stand-alone numeric keypad needs to be carried along with the electronic apparatus when location of use is changed. Therefore, portability of the electronic apparatus is greatly reduced.

What is needed, therefore, is a portable electronic apparatus employing a numeric keypad with space-saving and portable properties.

### SUMMARY OF THE INVENTION

A portable electronic apparatus includes a case defining a space therein and an opening communicating with the space, and an input module received in the space of the case and configured for inputting data to the electronic apparatus. The input module includes a chassis detachably attached to the case, and a numeric keypad movably attached to the chassis through the opening. The numeric keypad is capable of being exposed from the case when data entry is desired. The space is suitable to receive a data storage device of the electronic apparatus when the input module is removed from the case.

Other advantages and novel features will become more apparent from the following detailed description when taken in conjunction with the accompanying drawings, in which:

### BRIEF DESCRIPTION OF THE DRAWINGS

FIG. 1 is an isometric view of a portable electronic apparatus in accordance with a preferred embodiment;

FIG. 2 is an exploded, isometric view of the portable electronic apparatus of FIG. 1;

FIG. 3 is an exploded, isometric view of an input module of FIG. 2, with a chassis of the input module being secured within a case of the portable electronic apparatus;

FIG. 4 is an inverted, isometric view of a numeric keypad of the input module of FIG. 3;

FIG. 5 is an isometric view of the input module of FIG. 4 when it is in a retracted state, with the numeric keypad being removed;

FIG. 6 is an isometric view of the input module of FIG. 4 when it is in an ejecting state, with the numeric keypad being removed; and

FIG. 7 is an isometric view of the portable electronic apparatus of FIG. 1, with the numeric keypad being extended therefrom.

### DETAILED DESCRIPTION OF THE INVENTION

In the following embodiment, a portable electronic apparatus with an input module including a numeric keypad is used as an example for illustration. It is noted that the portable electronic apparatus in the embodiment may be a notebook computer or a laptop computer, and the numeric keypad in the embodiment may be also a slim type mouse or any other input module.

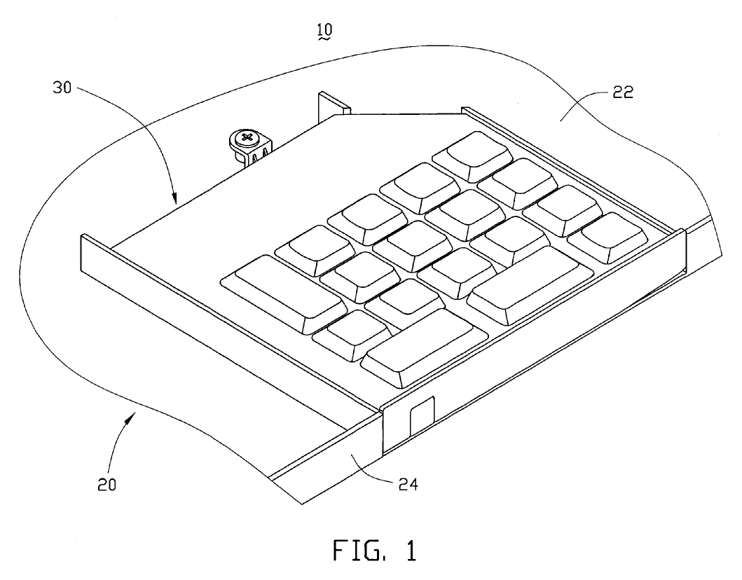

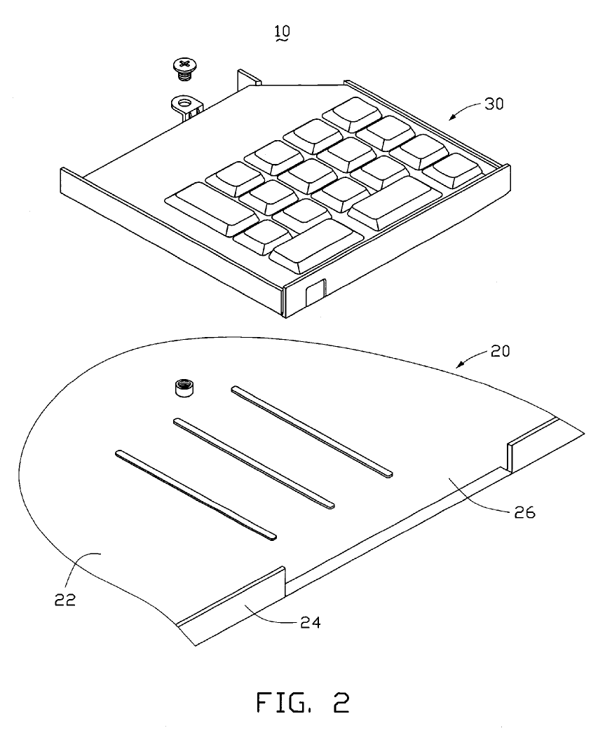

Referring to FIGS. 1 and 2, a portable electronic apparatus 10 in accordance with a preferred embodiment is illustrated. The portable electronic apparatus 10 includes a case 20 and an input module 30 received in a space of the case 20. The space is suitable to receive a data storage device, such as a slim optical disk drive, for the portable electronic apparatus 10 when the input module 30 is removed from the case 20.

The case 20 includes a floor 22 for locating the input module 30 thereon and a first sidewall 24 substantially perpendicularly extending from a periphery of the floor 22. An opening 26 is defined in the first sidewall 24 for the input module 30 to insert therethrough.

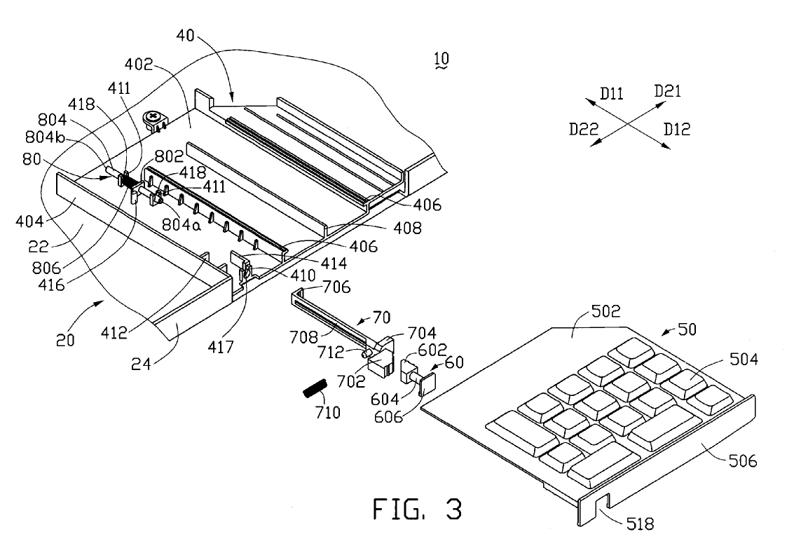

Referring also to FIG. 3, the input module 30 for inputting data includes a chassis 40, a numeric keypad 50, an operating member 60, a retaining member 70, and an ejecting member 80. The chassis 40 is secured on the floor 22. The numeric keypad 50 is movably received in the chassis 40 for entering input. Two opposite first directions D11 and D12 are respectively defined to indicate ways along which the numeric keypad 50 is loaded in and unloaded from the case 20. The operating member 60 is configured as a switch for unlocking the numeric keypad 50. The retaining member 70 is set in the chassis 40 and used for preventing the numeric keypad 50 from dropping out of the case 20. The ejecting member 80 is set in the chassis 40 for extending the numeric keypad 50 out from the case 20 along the first direction D12.

The chassis 40 includes a first base 402, a second sidewall 404, a pair of guiding portions 406, a supporting portion 408, a first bearing portion 410, a pair of second bearing portions 411, a pair of first limiting portions 412, a second limiting portion 414, and a third limiting portion 416. The second sidewall 404 substantially perpendicularly protrudes from a side of the first base 402 and is elongated along the first directions D11 or D12. The pair of guiding portions 406 and the supporting portion 408 may be an elongated board extending along the first directions D11 or D12. The guiding portions 406 are positioned on the first base 402 for engagably supporting and guiding the numeric keypad 50. The supporting portion 408 is substantially perpendicularly positioned on the first base 402 and between the pair of guiding portions 406 for supporting the numeric keypad 50. A deformation of the numeric keypad 50 due to its weight can thus be avoided. The first bearing portion 410 defines a first bearing hole 417 therethrough. Each second bearing portion 411 defines a second bearing hole 418 therethrough. The pair of first limiting portions 412 and the second limiting portion 414 may be boards. Two opposite second directions D21 and D22 are defined perpendicular to the first directions D11 and D12. The first limiting portions 412 perpendicularly protrude into the chassis 40 from the second sidewall 404 along the second direction D22 and are spaced from each other. The second limiting portion 414 protrudes from the first base 402 and extends along the first direction D11. The second limiting portion 414 is substantially perpendicular to and spaced from the pair of first limiting portions 412. The third limiting portion 416 may be a projection positioned on the first base 402 and opposite to the second limiting portion 414.

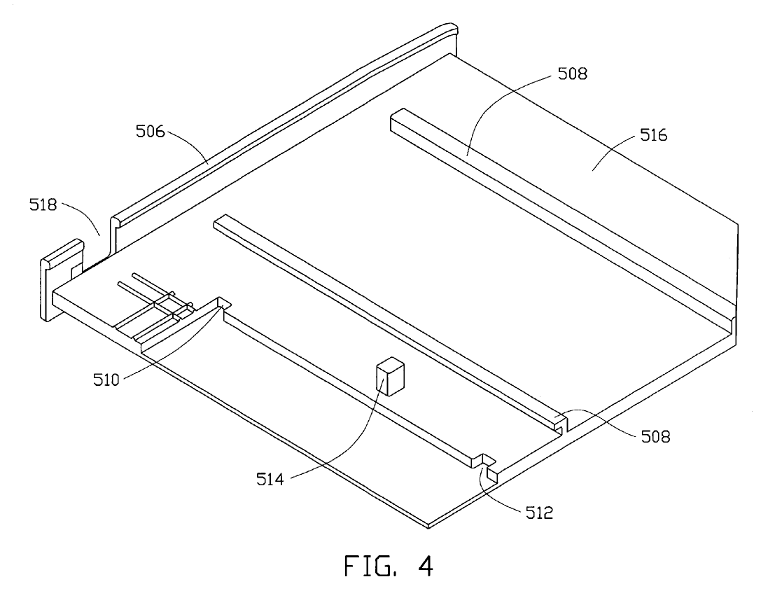

Referring also to FIG. 4, the numeric keypad 50 includes a second base 502 for locating a plurality of keys 504 thereon, a panel 506, a pair of complementary guiding portions 508, a first complementary blocking portion 510, a second complementary blocking portion 512, and a protrusion 514. The panel 506 attaches to a side of the second base 502 for detachably covering the opening 26. The pair of complementary guiding portion 508 may be elongated boards installed on a backside 516 of the second base 502 for engaging with the pair of guiding portions 406 located on the first base 402. The first and second complementary blocking portions 510 and 512 may be notches defined in the second base 502 for receiving the retaining member 70 therein. The protrusion 514 perpendicularly protrudes from the backside 516 of the second base 502 for being pressed by the ejecting member 80. A cutout 518 is defined in the panel 506 for the operating member 60 to insert therethrough. The keypad 50 is electrically coupled to a circuit board (not shown) of the portable electronic apparatus 10 via a cable (not shown).

The operating member 60 includes a first wedge portion 602, a first connecting portion 604, and a button portion 606 for a user to press. The first connecting portion 604 may be a shaft and interconnects the first wedge portion 602 and the button portion 606, and is movably supported by the first bearing portion 410 next to the opening 26.

The retaining member 70 includes a second wedge portion 702 engaging with the first wedge portion 602, a first blocking portion 704, a second blocking portion 706, a second connecting portion 708, and a first resilient portion 710. The first blocking portion 704 and the second blocking portion 706 may be clasps and are longitudinally arranged at two opposite ends of the second connecting portion 708. The second connecting portion 708 may be a rod or an elongated board with a positioning pin 712 protruding therefrom. The second wedge portion 702 connects to the first blocking portion 704. The first resilient portion 710 may be a spring which surrounds the positioning pin 712 and is positioned between the second connecting portion 708 and the second sidewall 404 for resiliently restricting a movement of the retaining member 70 towards the second sidewall 404.

The ejecting member 80 includes a third blocking portion 802, a pushing portion 804, and a second resilient portion 806. The pushing portion 804 protrudes out from two opposite sides of the third blocking portion 802 and is capable of traversing along the opposite directions D11 and D12. The pushing portion 804 has a first end 804a and an opposite second end 804b. The first and second ends 804a, 804b are respectively slidably supported by the pair of second bearing portions 411. The second resilient portion 806 surrounds the pushing portion 804 at one side of the third blocking portion 802 and is restricted between one of the two second bearing portions 411 and the third blocking portion 802.

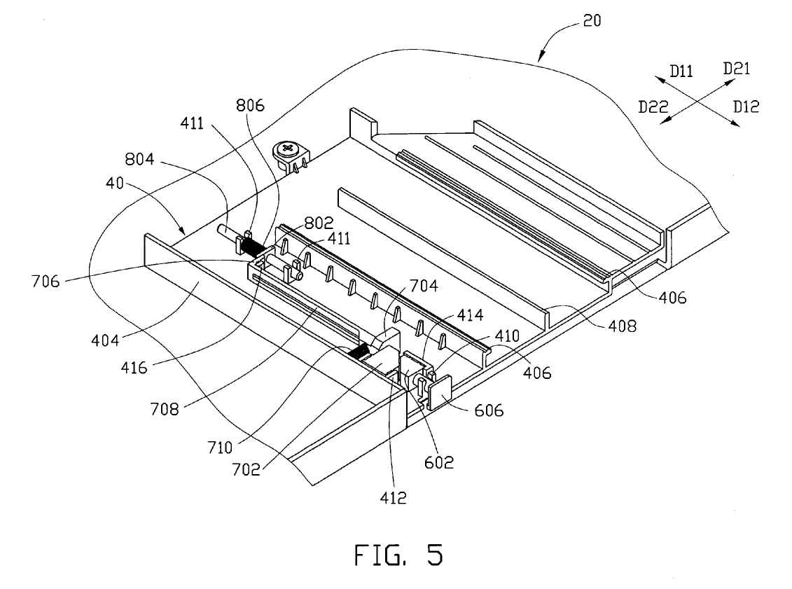

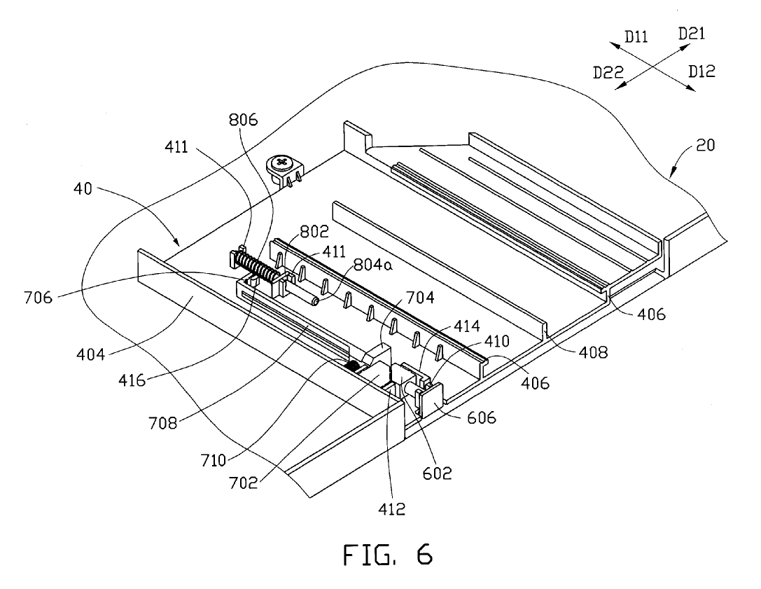

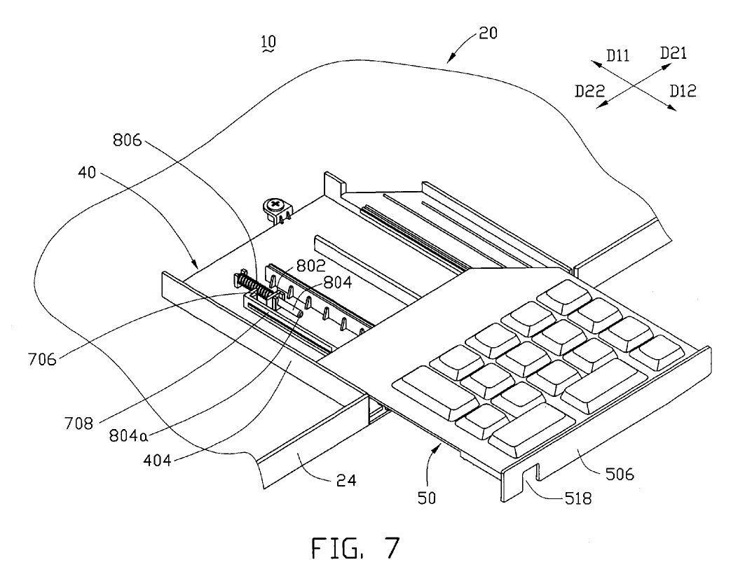

Referring also to FIGS. 5 to 7, in assembly, the chassis 40 is accommodated in the case 20 and secured on the floor 22. The first connecting portion 604 is inserted through the first bearing hole 417 of the first bearing portion 410. The first wedge portion 602 and the button portion 606 of the operating member 60 are arranged at two opposite sides of the first bearing portion 410. The first wedge portion 602 is guided by the second limiting portion 414 and movable along the opposite first directions D11 and D12. A deviation of the first wedge portion 602 along the second direction D21 is avoided. The second wedge portion 702 of the retaining member 70 is received between the pair of the first limiting portions 412 and is movable along the opposite second directions D21 and D22. The first blocking portion 704 partially overlaps the second limiting portion 414. The second blocking portion 706 is restricted and slidably guided by the third limiting portion 416. The retaining member 70 can thus be movable along the opposite second directions D21 and D22. The first end 804a and the second end 804b of the pushing portion 804 are inserted through the corresponding second bearing holes 418 and supported by the pair of second bearing portions 411. The pushing portion 804 is movable along the opposite second directions D21 and D22. The second resilient portion 806 surrounds on the pushing portion 804 and is restricted between the third blocking portion 802 and one of the second bearing portions 411. The numeric keypad 50 is inserted into the case 20 and movably covers the chassis 40. The pair of complementary guiding portions 508, which protrude from the backside 516 of the second base 502, movably engage with and are supported by the pair of the guiding portion 406. The protrusion 514 aligns with the pushing portion 804. An interaction is generated between the protrusion 514 and the pushing portion 804 so that the second resilient member 806 may be compressed for storing energy. The third blocking portion 802 detachably engages with the second blocking portion 706. The first blocking portion 704 thus engages with the complementary blocking portion 510 so that the numeric keypad 50 is locked in the case 20. The button portion 606 is detachably inserted into the cutout 518 but remains exposed for use.

To use the numeric keypad 50, the user presses the button portion 606 to push the operating member 60 to move into the chassis 40 along the first direction D11. The first wedge portion 602 engages with the second wedge portion 702. A pressure is thus applied to the second wedge portion 702 via the first wedge portion 602. The second wedge portion 702 is driven to move close to the second sidewall 404 along the second direction D22. The first resilient portion 710 is compressed. The first blocking portion 704 separates from the complementary blocking portion 510 while the second blocking portion 706 separates from the third blocking portion 802. The stored energy in the second resilient portion 806 is released and the second resilient portion 806 urges the third blocking portion 802 to move along the first direction D12 to cause the first end 804a of the pushing portion 804 to thereby push the protrusion 514 of the numeric keypad 50 out of the case 20 along the first direction D12. When pushing of the operating member 60 ceases, the energy in the first resilient portion 710 is also released to drive the first blocking portion 704 to deviate from the second sidewall 404. Another complementary blocking portion 512 is stopped by the first blocking portion 704 returned by the first resilient portion 710 when the numeric keypad 50 is almost completely exposed from the case 20. The keys 504 arranged on the second base 502 are now exposed for data entry by the user.

When the portable electronic apparatus 10 is in motion, the numeric keypad 50 is stored within the case 20 in a retracted state. The user presses the button portion 606 again to push the retaining member 70 to move towards the second sidewall 404. The first blocking portion 704 is separated from the complementary blocking portion 512 to unblock the numeric keypad 50. The numeric keypad 50 can thus be pushed into the case 20. The protrusion 514 is in contact with and causes the first end 804a of the pushing portion 804 to withdraw. The first blocking portion 704 engages with the complementary blocking portion 510 to block the numeric keypad 50 when the numeric keypad 50 is substantially retracted into the case 20.

In alternative embodiments, the ejecting member 80 may be canceled. The numeric keypad 50 may be pulled out from the case 20 by fingers of the user instead of the ejecting member 80. The first base 402 and even the chassis 40 may be omitted. The operating member 60, the retaining member 70, and the ejecting member 80 may be directly mounted on the floor 22 of the case 20. The pair of guiding portions 406 and supporting portion 408 may be omitted or directly located on the floor 22. The pair of first limiting portions 412 may extend from the first base 402 or directly protrude from the floor 22.

It is believed that the present invention and its advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A portable electronic apparatus comprising:
a case defining a space therein and an opening communicating with the space; and
an input module received in the space of the case and configured for inputting data to the electronic apparatus, the input module comprising a chassis detachably attached to the case, and a numeric keypad movably attached to the chassis through the opening, the numeric keypad being capable of being exposed from the case when data entry is desired, wherein the space is suitable to receive a data storage device of the electronic apparatus when the input module is removed from the case.

2. The portable electronic apparatus as claimed in claim 1, wherein the input module further comprises a retaining member set on the chassis for releasably retaining the numeric keypad to stay at selective positions, and an operating member engaging with the retaining member for controlling the retaining member to release or retain the numeric keypad.

3. The portable electronic apparatus as claimed in claim 2, wherein the chassis comprises a first base, at least one sidewall substantially perpendicularly protruding from a side of the first base and extending along a first direction along which the numeric keypad is loaded into the chassis, a first bearing portion arranged on the first base and next to the opening for supporting the operating member, a pair of first limiting portions configured for guiding movement of the retaining member, and a second limiting portion configured for guiding movement of the operating member.

4. The portable electronic apparatus as claimed in claim 3, wherein the two first limiting portions protrude from the at least one sidewall into the chassis along a second direction substantially perpendicular to the first direction and spaced from each other for preventing the retaining member from moving along the first direction.

5. The portable electronic apparatus as claimed in claim 4, wherein the second limiting portion perpendicularly protrudes from the first base, and extends along the first direction and is spaced from the two first limiting portions for preventing the retaining member from moving along the second direction.

6. The portable electronic apparatus as claimed in claim 3, wherein the operating member comprises a first wedge portion configured for driving the retaining member, a button portion for being pressed thereon, and a first connecting portion interconnecting the first wedge portion and the button portion, the first connecting portion is movably supported by the first bearing portion.

7. The portable electronic apparatus as claimed in claim 6, wherein the retaining member comprises a second wedge portion engaging with the first wedge portion, a first blocking portion for detachably blocking the numeric keypad, and a first resilient portion positioned between the at least one sidewall and the first blocking portion for urging the first blocking portion to block the numeric keypad.

8. The portable electronic apparatus as claimed in claim 7, wherein the input module further comprises an ejecting member set in the chassis and configured for ejecting the numeric keypad out of the case, the retaining member further comprises a second blocking portion for controlling whether an ejection of the ejecting member is performed.

9. The portable electronic apparatus as claimed in claim 8, wherein the ejecting member comprises a third blocking portion, a pushing portion substantially perpendicularly protruding out from two opposite sides of the third blocking portion for pushing the keypad outward, and a second resilient portion surrounding the pushing portion at one side of the third blocking portion, the second blocking portion engaging with the third blocking portion to limit the pushing portion to move when the first blocking portion engages with the keypad, the second blocking portion disengaging from the third blocking portion to allow the pushing portion to be movable when the first blocking portion is disengaged from the keypad.

10. The portable electronic apparatus as claimed in claim 9, wherein the chassis further comprises a pair of second bearing portions aligned along the first direction, two free ends of the pushing portion are respectively slidably supported by the pair of second bearing portions, the second resilient portion is restricted between one of the second bearing portions and the third blocking portion.

11. The portable electronic apparatus as claimed in claim 9, wherein the numeric keypad includes a second base for locating a plurality of keys thereon, a panel attached on a side of the chassis for detachably covering the opening, a pair of complementary blocking portions formed in a backside of the second base for being selectively detachably blocked by the first blocking portion, and a protrusion configured on the backside for being pressed by the ejecting member.

12. The portable electronic apparatus as claimed in claim 11, wherein the chassis further comprises at least one guiding portion positioned on the first base and extending along the first direction, the numeric keypad further comprises at least one complementary guiding portion slidably engaging with the at least one guiding portion of the chassis.

13. The portable electronic apparatus as claimed in claim 11, wherein a cutout is defined in the panel for exposing the button to outside of the case.

14. The portable electronic apparatus as claimed in claim 5, wherein the third limiting portion perpendicularly protrudes from the first base and is substantially aligned with the second limiting portion for preventing a deviation of the retaining member.

15. The portable electronic apparatus as claimed in claim 1, wherein the case further comprises a wall, the opening is defined in the wall.

16. A portable electronic apparatus comprising:
a case defining an opening therein; and
a numeric keypad configured for inputting data to the electronic apparatus and movably received in the case via the opening, the numeric keypad exposable from the case for use, wherein a data storage device of the electronic apparatus is suitable to be received in the case via the opening when the input module is removed from the case.

17. The portable electronic apparatus as claimed in claim 16, further comprising a retaining member located in the case for releasably retaining the numeric keypad to stay at selective positions.

18. The portable electronic apparatus as claimed in claim 17, further comprising an operating member located in the case for engaging with the retaining member for activating the retaining member to retain or release the numeric keypad.

19. The portable electronic apparatus as claimed in claim 17, further comprising an ejecting member located in the case for ejecting the numeric keypad out from the case when the retaining member releases the numeric keypad.

20. A portable electronic apparatus comprising:
a case defining a space and an opening communicating the space with outside of the case;
an input module received in the space of the case and configured for inputting data to the electronic apparatus, the input module comprising a chassis detachably attached to the case in the space thereof, and a numeric keypad movably attached to the chassis through the opening; and
a locking device for locking the keypad to the chassis, the locking device comprising a button exposed to the outside of the case which allows the locking device to be unlocked from the keypad via operation on the button and the keypad to be moved out of the case for data entry; wherein
the space is suitable to receive a data storage device for the elctronic apparatus when the input module and the locking device are removed from the case.

21. The portable electronic apparatus as claimed in claim 21, wherein the locking device comprises a retaining member for releasably retaining the keypad to stay at selective positions, and an operating member for activating the retaining member to retain or release the numeric keypad, the operating member being movable in a first direction to activate the retaining member to move in a second direction perpendicular to the first direction, the button being formed at the operating member.
